(19) United States
(12) Patent Application Publication
(10) Pub. No.: US 2026/0369551 A1
(43) Pub. Date: Nov. 19, 2026

(54) POSITIVE ELECTRODE PLATE, METHOD FOR EVALUATING ELECTROCHEMICAL PERFORMANCE OF POSITIVE ELECTRODE PLATE, SOLID-STATE BATTERY, AND ELECTRIC DEVICE

(71) Applicant: BYD COMPANY LIMITED, Shenzhen (CN)

(72) Inventors: Guoshuai WANG, Shenzhen (CN); Guangui YI, Shenzhen (CN); Zizhu GUO, Shenzhen (CN)

(73) Assignee: BYD COMPANY LIMITED, Shenzhen (CN)

(21) Appl. No.: 19/722,563

(22) Filed: Jun. 26, 2026

Related U.S. Application Data
(63) Continuation of application No. PCT/CN2024/121574, filed on Sep. 26, 2024.

(30) Foreign Application Priority Data
Dec. 29, 2023 (CN) 202311871551.0

(51) Int. Cl. H01M 4/13; H01M 4/02; H01M 10/0525; H01M 10/0562

(52) U.S. Cl. CPC H01M 4/13; H01M 10/0562; H01M 2004/021; H01M 2004/028; H01M 10/0525

(57) ABSTRACT

A positive electrode plate includes a positive electrode active material layer that includes a positive electrode active material, a positive electrode electrolyte, and pores within the positive electrode active material layer. In a vertical cross-section of the positive electrode active material layer taken along a thickness direction, a length ration of a total length L₁ of a first type of contact interface between the positive electrode active material and the positive electrode electrolyte, a total length L₂ of a second type of contact interface between different portions or particles of the positive electrode active material, and a total length L₃ of a third type of contact interface between the positive electrode active material and the pores satisfies L₁:L₂:L₃=(80-99):(1-20):(0-5), and a sum of L₁, L₂, and L₃ is 100. Method and solid-state battery counterparts are also contemplated.

### CROSS-REFERENCE TO RELATED APPLICATIONS

The present application is a continuation of International Application No. PCT/CN2024/121574, filed on Sep. 26, 2024, which claims priority to Chinese Patent Application No. 202311871551.0, filed on Dec. 29, 2023, entitled “POSITIVE ELECTRODE PLATE, METHOD FOR EVALUATING ELECTROCHEMICAL PERFORMANCE OF POSITIVE ELECTRODE PLATE, SOLID-STATE BATTERY, AND ELECTRIC DEVICE.” The entire disclosures of the prior applications are hereby incorporated by reference.

### TECHNICAL FIELD

The present disclosure relates to the field of batteries, including a positive electrode plate, a method for evaluating an electrochemical performance of a positive electrode plate, a solid-state battery, and an electric device.

### BACKGROUND

At present, solid-state batteries are being studied due to high energy density and high safety. In a solid-state battery, the contact between internal solid particles in the positive electrode plate determines the construction of ion pathways and electron pathways, thereby directly affecting the electrical performance of the solid-state battery. Many studies are focused on the contact between the positive electrode plate and the solid-state electrolyte layer, but the contact state of the internal particles in the positive electrode active material layer of the positive electrode plate may be ignored. Also, there is no effective method to evaluate the construction of the ion pathways and the electron pathways in the positive electrode active material layer.

### SUMMARY

In view of this, the present disclosure includes a positive electrode plate, a method for evaluating an electrochemical performance of a positive electrode plate, a solid-state battery, and an electric device. The positive electrode plate has low resistance, high specific capacity, and high ionic conductivity, and has improved electrochemical performance, which helps to improve the performance of the solid-state battery. The method for evaluating the electrochemical performance of the positive electrode plate is simple, has a wide range of applications, classifies and evaluates the contact state of the internal particles in the positive electrode plate, improves ionic conduction pathway and capacity, and improves the electrochemical performance of the positive electrode plate.

In a first aspect, the present disclosure includes a positive electrode plate, and the positive electrode plate includes a positive electrode current collector and a positive electrode active material layer on a surface of the positive electrode current collector. The positive electrode active material layer includes a positive electrode active material and a positive electrode electrolyte, and pores exist within the positive electrode active material layer. In a vertical cross-section of the positive electrode active material layer taken along a thickness direction, a total length of a first type of contact interface between the positive electrode active material and the positive electrode electrolyte is denoted as a total length L₁, a total length of a second type of contact interface between different portions or particles of the positive electrode active material is denoted as a total length L₂, and a total length of a third type of contact interface between the positive electrode active material and the pores is denoted as a total length L₃. A length ratio of the total length L₁ of the first type of contact interface, the total length L₂ of the second type of contact interface, and the total length L₃ of the third type of contact interface satisfies L₁:L₂:L₃=(80-99):(1-20):(0-5), and a sum of L₁, L₂, and L₃ is 100.

In an embodiment of the present disclosure, the length ratio of the total length L₁ of the first type of contact interface, the total length L₂ of the second type of contact interface, and the total length L₃ of the third type of contact interface satisfies L₁:L₂:L₃=(85-95):(5-15):(0-2), and the sum of L₁, L₂, and L₃ is 100.

In an embodiment of the present disclosure, the mass percentage of the positive electrode active material in the positive electrode active material layer ranges from 50% to 90%, and the mass percentage of the positive electrode electrolyte in the positive electrode active material layer ranges from 10% to 50%.

In an embodiment of the present disclosure, the volume percentage of the pores in the positive electrode active material layer is less than or equal to 5%, and a pore size of the pores ranges from 0.1 μm to 5 μm.

In an embodiment of the present disclosure, the positive electrode active material includes at least one of lithium iron phosphate, lithium cobalt oxide, lithium manganese oxide, lithium nickel cobalt aluminum oxide, lithium nickel cobalt manganese oxide, and lithium nickel manganese oxide, and the positive electrode electrolyte includes at least one of an oxide electrolyte, a sulfide electrolyte, and a polymer electrolyte.

In an embodiment of the present disclosure, the sulfide electrolyte includes at least one of Li₃PS₄, Li_{5.5}PS_{4.5}Cl_{1.5}, Li₇P₃S₁₁, Li₁₁GeP₂S₁₂, Li₆PS₅Cl, Li₇P₂S₈I, Li₁₀SnP₂S₁₂ and Li_{3.25}Ge_{0.25}P_{0.75}S₄.

In the positive electrode plate described in the present disclosure, by controlling the three types of contact in the positive electrode active material layer—the contact between the positive electrode active material and the positive electrode electrolyte, the contact between the positive electrode active material and the positive electrode active material, and the contact between the positive electrode active material and the pores-within an appropriate proportion range, a large number of ionic conduction pathways can be formed in the positive electrode plate, thereby improving ionic conductivity, which helps to increase the specific capacity of the positive electrode plate and improve the electrochemical performance of the positive electrode plate.

In a second aspect, the present disclosure includes a method for evaluating electrochemical performance of a positive electrode plate. In the method, a positive electrode plate is cut along a thickness direction of the positive electrode plate to expose a vertical cross-section of a positive electrode active material layer of the positive electrode plate that is on a positive electrode current collector of the positive electrode plate. The positive electrode active material layer includes a positive electrode active material and a positive electrode electrolyte, and pores are within the positive electrode active material layer. A total length L₁ of a first type of contact interface between the positive electrode active material and the positive electrode electrolyte, a total length L₂ of a second type of contact interface between different portions or particles of the positive electrode active material, and a total length L₃ of a third type of contact interface between the positive electrode active material and the pores are acquired through a characterization means. A ratio L₁:L₂:L₃ of the total length L₁ of the first type of contact interface, the total length L₂ of the second type of contact interface, and the total length L₃ of the third type of contact interface is calculated. In the method, the electrochemical performance of the positive electrode plate is evaluated based on whether L₁:L₂:L₃ satisfies L₁:L₂:L₃=(80-99):(1-20):(0-5), and a sum of L₁, L₂, and L₃ is 100.

The method for evaluating the electrochemical performance of the positive electrode plate described in the present disclosure has a simple evaluation process and a wide range of application, and can quickly evaluate the electrochemical performance of the positive electrode plate.

In a third aspect, the present disclosure includes a positive electrode plate that includes a positive electrode active material layer. The positive electrode active material layer includes a positive electrode active material and a positive electrode electrolyte, and pores are within the positive electrode active material layer. In the positive electrode active material layer, a total area of a first type of contact interface between the positive electrode active material and the positive electrode electrolyte is denoted as a total area S₁, a total area of a second type of contact interface between different portions or particles of the positive electrode active material is denoted as a total area S₂, and a total area of a third type of contact interface between the positive electrode active material and the pores is denoted as a total area S₃. An area ratio of the total area S₁ of the first type of contact interface, the total area S₂ of the second type of contact interface, and the total area S₃ of the third type of contact interface satisfies S₁:S₂:S₃=(80-99):(1-20):(0-5), and a sum of S₁, S₂, and S₃ is 100.

In the positive electrode plate described in the present disclosure, by controlling the three types of contact in the positive electrode active material layer—the contact between the positive electrode active material and the positive electrode electrolyte, the contact between the positive electrode active material and the positive electrode active material, and the contact between the positive electrode active material and the pores-within an appropriate proportion range, a large number of ionic conduction pathways can be formed in the positive electrode plate, thereby improving ionic conductivity, which helps to increase the specific capacity of the positive electrode plate and improve the electrochemical performance of the positive electrode plate.

In a fourth aspect, the present disclosure includes a solid-state battery. The solid-state battery includes a positive electrode plate and a solid-state electrolyte layer on a surface of the positive electrode plate, and the positive electrode plate includes the positive electrode plate according to the first aspect or the third aspect.

In an embodiment of the present disclosure, the solid-state electrolyte layer includes at least one of an oxide electrolyte, a sulfide electrolyte, and a polymer electrolyte.

The solid-state battery described in the present disclosure has improved electrochemical performance and high safety, which supports the widespread use of solid-state batteries.

In a fifth aspect, the present disclosure includes an electric device, and the electric device includes the solid-state battery according to the fourth aspect.

The electric device described in the present disclosure has improved overall performance and strong market competitiveness.

### BRIEF DESCRIPTION OF THE DRAWINGS

In order to illustrate the technical solutions in the embodiments of the present disclosure, the following briefly describes the accompanying drawings that are used to describe one or more embodiments of this disclosure. Embodiments described herein are used to explain the present disclosure, and are not intended to limit the present disclosure.

FIG. 1 is a cross-section of a positive electrode plate according to an embodiment of the present disclosure;

FIG. 2 is an enlarged view of the dashed line area in FIG. 1;

FIG. 3 is a cross-section structure of a solid-state battery according to an embodiment of the present disclosure; and

FIG. 4 is a scanning electron microscope (SEM) image of a cross-section of a positive electrode active material layer according to an embodiment of the present disclosure.

### DETAILED DESCRIPTION

The following describes technical solutions in embodiments of this disclosure with reference to the accompanying drawings. The described embodiments are some of the embodiments of this disclosure rather than all of the embodiments. Other embodiments are within the scope of this disclosure.

The use of “at least one of” or “one of” in the disclosure is intended to include any one or a combination of the recited elements. For example, references to at least one of A, B, or C; at least one of A, B, and C; at least one of A, B, and/or C; and at least one of A to C are intended to include only A, only B, only C or any combination thereof. References to one of A or B and one of A and B are intended to include A or B or (A and B). The use of “one of” does not preclude any combination of the recited elements when applicable, such as when the elements are not mutually exclusive.

Examples of terms involved in the aspects of the disclosure are briefly introduced. The descriptions of the terms are provided as examples only and are not intended to limit the scope of the disclosure.

Technical solutions in one or more embodiments of the present disclosure will be described below in combination with the accompanying drawings. The described embodiments are some of the embodiments of the present disclosure, rather than all the embodiments. Based on the embodiments in the present disclosure, other embodiments without deviating from the present disclosure are within the scope of the present disclosure.

Many examples focus on the contact between the positive electrode plate and the solid-state electrolyte layer in the solid-state batteries, thereby improving the ionic conduction pathway between the positive electrode plate and the solid-state electrolyte layer. However, for the positive electrode active material layer of the positive electrode plate, how to determine the contact state of the internal particles in the positive electrode active material layer and how to ensure the effective construction of the ion pathways and the electron pathways of the positive electrode active material layer have not been reported or studied. In some examples, the problems of increased resistance, reduced specific capacity, and decreased electrochemical performance of the solid-state battery caused by the unbalanced construction of the ion pathways and the electron pathways of the positive electrode plate may still exist.

To solve the above technical problem, the present disclosure includes a positive electrode plate and a method for evaluating electrochemical performance of a positive electrode plate. In some aspects, the positive electrode plate may have the advantages of low resistance, high specific capacity, and high ionic conductivity, and has improved overall performance. In some examples, the method for evaluating the electrochemical performance of the positive electrode plate is simple, the contact state of the internal particles in the positive electrode active material layer in the positive electrode plate is classified and evaluated, and the electrochemical performance of the positive electrode plate can be further quickly evaluated.

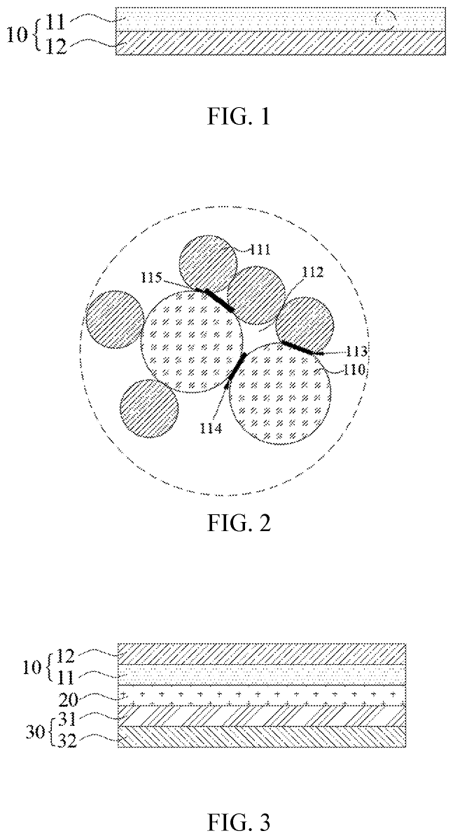

Referring to FIG. 1 and FIG. 2, FIG. 1 is a schematic diagram of a cross-section of a positive electrode plate according to an embodiment of the present disclosure, and FIG. 2 is an enlarged view of the dashed line area in FIG. 1. A positive electrode plate 10 includes a positive electrode current collector 12 and a positive electrode active material layer 11 on the surface of the positive electrode current collector 12. The positive electrode active material layer 11 includes a positive electrode active material 110 and a positive electrode electrolyte 111, and pores 112 exist within the positive electrode active material layer. A contact interface between the positive electrode active material 110 and the positive electrode electrolyte 111 is denoted as a first type of contact interface 113, a contact interface between different portions or particles of the positive electrode active material 110 is denoted as a second type of contact interface 114, and a contact interface between the positive electrode active material 110 and the pores 112 is denoted as a third type of contact interface 115. In at least one vertical cross-section of the positive electrode active material layer taken along a thickness direction, a total length of the first type of contact interface 113 between the positive electrode active material 110 and the positive electrode electrolyte 111 is denoted as the total length L₁, a total length of the second type of contact interface 114 between different portions or particles of the positive electrode active material 110 is denoted as the total length L₂, and a total length of the third type of contact interface 115 between the positive electrode active material 110 and the pores 112 is denoted as the total length L₃. In some examples, a length ratio of L₁:L₂:L₃ satisfies L₁:L₂:L₃=(80-99):(1-20):(0-5), and a sum of L₁, L₂, and L₃ is 100.

In some aspects, the positive electrode plate described in the present disclosure has a high proportion of the total length L₁ of the first type of contact interface. In some examples, the contact interface between the positive electrode active material and the positive electrode electrolyte in the active material layer is relatively large, the ion transfer may occur widely, the pathways for ion intercalation and deintercalation are increased, and the ionic conductivity and specific capacity of the positive electrode plate are improved. In some aspects, the total length L₂ of the second type of contact interface as described in this disclosure may improve a number of electronic conduction pathways and maintain a low resistance of the positive electrode plate. In some aspects, the total length L₃ of the third type of contact interface may reflect the contact state between the positive electrode active material and the pores. In some aspects, the contact may not participate in the construction of the electronic conduction and ionic conduction pathways, may correspond to an ineffective contact, and may not affect the electrochemical performance of the positive electrode plate. In some aspects, the proportion of the total length L₃ of the third type of contact interface may be controlled to be relatively low, which helps to improve the performance of the positive electrode plate. In one or more embodiments of the positive electrode plate provided in the present disclosure, by controlling the proportion range of three types of contacts in the positive electrode active material layer, such as the contact between the positive electrode active material and the positive electrode electrolyte, the contact between different portions or particles of the positive electrode active material, and the contact between the positive electrode active material and the pores, the number of ionic conduction pathways in the positive electrode plate may be increased, the number of electronic conduction pathways may be controlled, the ionic conductivity and specific capacity may be improved, the resistance of the positive electrode plate may be reduced, and thus the overall electrochemical performance of the positive electrode plate is improved.

In the present disclosure, at least one vertical cross-section of the positive electrode active material layer is taken to perform proportion statistics of the total length of the first type of contact interface, the total length of the second type of contact interface, and the total length of the third type of contact interface. The at least one vertical cross-section can be one or more (two or more) vertical cross-sections. Taking multiple cross-sections of the positive electrode active material layer to perform the statistics of the total length of the first type of contact interface, the total length of the second type of contact interface, and the total length of the third type of contact interface helps to obtain the positive electrode active material layer with improved performance. In some examples, the number of the vertical cross-sections of the positive electrode active material layer taken can be, but is not limited to, 1, 2, 3, 5, 8, 10, 15, 20, or 50, etc. In an embodiment of the present disclosure, the number of the vertical cross-sections of the positive electrode active material layer taken can range from 2 to 10.

It should be noted that when multiple vertical cross-sections are taken, the total length L₁ of the first type of contact interface is acquired by adding the lengths of all the first type of contact interfaces 113 in the multiple vertical cross-sections; the total length L₂ of the second type of contact interface is acquired by adding the lengths of all the second type of contact interfaces 114 in the multiple vertical cross-sections; and the total length L₃ of the third type of contact interface is acquired by adding the lengths of all the third type of contact interfaces 115 in the multiple vertical cross-sections. When multiple vertical cross-sections are taken, the vertical cross-sections can be uniformly spaced and distributed in the positive electrode active material layer.

In the present disclosure, in the at least one vertical cross-section, the total length of the contact interface between the positive electrode active material and the positive electrode electrolyte is denoted as the total length L₁ of the first type of contact interface. In the positive electrode active material layer, the positive electrode active material and the positive electrode electrolyte are in contact with each other, and the contact position is the main location where ion transfer occurs. In some aspects, the larger the contact area, the higher the ion mobility and the higher the ionic conductivity. For convenience of characterization, the present disclosure uses the length of the contact interface between the positive electrode active material and the positive electrode electrolyte in the vertical cross-section of the positive electrode active material layer for evaluation, and statistically calculates the total length of the contact interface between the positive electrode active material and the positive electrode electrolyte in the vertical cross-section to reflect the contact state between the positive electrode active material and the positive electrode electrolyte in the positive electrode active material layer.

In the present disclosure, in the at least one vertical cross-section, the total length of the contact interface between the positive electrode active material and the positive electrode active material is denoted as the total length L₂ of the second type of contact interface. In the positive electrode active material layer, the positive electrode active material and the positive electrode active material are in contact with each other, and the contact position provides a transmission channel for electrons in the positive electrode plate, but excessively high electronic conductivity can exacerbate side reactions of the electrolyte and increase the resistance of the positive electrode plate. Therefore, controlling the contact area between different portions or particles of the positive electrode active material helps ensure that the positive electrode plate has a relatively low resistance and adequate electronic conductivity. For convenience of characterization, the present disclosure uses the length of the contact interface between the positive electrode active material and the positive electrode active material in the vertical cross-section of the positive electrode active material layer for evaluation, and statistically calculates the total length of the contact interface between the positive electrode active material and the positive electrode active material in the vertical cross-section to reflect the contact state between the positive electrode active material and the positive electrode active material in the positive electrode active material layer.

In the present disclosure, in the at least one vertical cross-section, the total length of the contact interface between the positive electrode active material and the pores is denoted as the total length L₃ of the third type of contact interface. Referring to FIG. 2, the positive electrode active material and the pores are in contact with each other. In some aspects, a part of the positive electrode active material is exposed in the pores and constitutes a complete pore boundary with other particles, and the part of the positive electrode active material that participates in the formation of the pore boundary and is exposed in the pores is the contact interface between the positive electrode active material and the pores (e.g., the third type of contact interface). In the positive electrode active material layer, mixing, coating, and other processes can lead to pores within the positive electrode active material layer, and the pores may not participate in the construction of ion pathways and electron pathways and may not contribute to the electrochemical performance of the positive electrode plate. Controlling the total area of the type of contact between the positive electrode active material and the pores within a small range can reduce the adverse effects of the pores on the positive electrode plate. The contact condition between the positive electrode active material and the pores is evaluated by using the length of the contact interface between the positive electrode active material and the pores in the vertical cross-section of the positive electrode active material layer, and the total length of the contact interface between the positive electrode active material and the pores in the vertical cross-section is statistically calculated to reflect the contact state between the positive electrode active material and the pores in the positive electrode active material layer.

In the present disclosure, the length ratio of the total length L₁ of the first type of contact interface, the total length L₂ of the second type of contact interface, and the total length L₃ of the third type of contact interface satisfies L₁:L₂:L₃-(80-99):(1-20):(0-5), and the sum of L₁, L₂, and L₃ is 100. In some examples, the length ratio of the total length L₁ of the first type of contact interface, the total length L₂ of the second type of contact interface, and the total length L₃ of the third type of contact interface can be, but is not limited to, 80:(1-20):(0-5), 85:(1-20):(0-5), 90:(1-20):(0-5), 95:(1-20):(0-5), 99:(1-20):(0-5), (80-99):5:(0-5), (80-99):15:(0-5), (80-99):20:(0-5), (80-99):(1-20):0, (80-99):(1-20):2, or (80-99):(1-20):5, etc. In an embodiment of the present disclosure, the length ratio of the total length L₁ of the first type of contact interface, the total length L₂ of the second type of contact interface, and the total length L₃ of the third type of contact interface satisfies L₁:L₂:L₃=(85-95):(5-10):(0-2), which can improve the ionic conductivity and specific capacity of the positive electrode plate.

In an embodiment of the present disclosure, the positive electrode active material can aggregate a large number of ions, thereby improving the ionic conductivity and electronic conductivity of the positive electrode plate. In some examples, the positive electrode active material can include, but is not limited to, at least one of lithium iron phosphate, lithium cobalt oxide, lithium manganese oxide, lithium nickel cobalt aluminum oxide, and lithium nickel cobalt manganese oxide. In an embodiment of the present disclosure, the positive electrode active material can be lithium iron phosphate. In another embodiment of the present disclosure, the positive electrode active material can be lithium manganese oxide.

In an embodiment of the present disclosure, the positive electrode electrolyte provides sites for the deintercalation and intercalation of ions, thereby increasing the number of ion pathways. In some examples, the positive electrode electrolyte can include, but is not limited to, at least one of an oxide electrolyte, a sulfide electrolyte, and a polymer electrolyte. For example, the sulfide electrolyte can include, but is not limited to, at least one of Li₃PS₄, Li_{5.5}PS_{4.5}Cl_{1.5}, Li₇P₃S₁₁, Li₁₁GeP₂S₁₂, Li₆PS₅Cl, Li₇P₂S₈I, Li₁₀SnP₂S₁₂ and Li_{3.25}Ge_{0.25}P_{0.75}S₄. In an embodiment of the present disclosure, when the positive electrode electrolyte is the sulfide electrolyte, the positive electrode electrolyte is Li₁₁GeP₂S₁₂. In another embodiment of the present disclosure, the positive electrode electrolyte can be the oxide electrolyte. In an embodiment of the present disclosure, the positive electrode current collector can include, but is not limited to, at least one of copper, aluminum, nickel, and stainless steel. In an embodiment of the present disclosure, the positive electrode current collector can be an aluminum foil.

In an embodiment of the present disclosure, the positive electrode active material layer further includes a binder, which can enhance the binding ability between the positive electrode active material layer and the positive electrode current collector. In some examples, the binder can include, but is not limited to, at least one of polyvinylidene fluoride, polyvinylidene difluoride, polytetrafluoroethylene, polyethylene, polypropylene, polystyrene, polybutadiene, acrylic resin, epoxy resin, polyethylene oxide, sodium carboxymethyl cellulose, and styrene-butadiene latex. In an embodiment of the present disclosure, the binder can be sodium carboxymethyl cellulose. In another embodiment of the present disclosure, the binder can be epoxy resin.

In an embodiment of the present disclosure, the mass percentage of the positive electrode active material in the positive electrode active material layer ranges from 50% to 90%. In some examples, the mass percentage of the positive electrode active material in the positive electrode active material layer can be, but is not limited to, 50%, 55%, 60%, 70%, 80%, or 90%, etc. In an embodiment of the present disclosure, the mass percentage of the positive electrode active material in the positive electrode active material layer ranges from 50% to 75%. In another embodiment of the present disclosure, the mass percentage of the positive electrode active material in the positive electrode active material layer ranges from 70% to 90%.

In an embodiment of the present disclosure, the D50 particle size of the positive electrode active material ranges from 2 μm to 6 μm, which can improve the specific capacity and ionic conductivity of the positive electrode plate. In some examples, the D50 particle size of the positive electrode active material can be, but is not limited to, 2 μm, 3 μm, 4 μm, 5 μm, or 6 μm, etc. In an embodiment of the present disclosure, the D50 particle size of the positive electrode active material ranges from 2 μm to 4 μm. In another embodiment of the present disclosure, the D50 particle size of the positive electrode active material ranges from 3 μm to 6 μm.

In an embodiment of the present disclosure, the mass percentage of the positive electrode electrolyte in the positive electrode active material layer ranges from 10% to 50%. In some examples, the mass percentage of the positive electrode electrolyte in the positive electrode active material layer can be, but is not limited to, 10%, 15%, 20%, 25%, 30%, 35%, 40%, or 50%, etc. In an embodiment of the present disclosure, the mass percentage of the positive electrode electrolyte in the positive electrode active material layer ranges from 10% to 45%. In another embodiment of the present disclosure, the mass percentage of the positive electrode electrolyte in the positive electrode active material layer ranges from 20% to 50%.

In an embodiment of the present disclosure, the D50 particle size of the positive electrode electrolyte ranges from 1 μm to 5 μm, which can improve the specific capacity and ionic conductivity of the positive electrode plate. In some examples, the D50 particle size of the positive electrode electrolyte can be, but is not limited to, 1 μm, 2 μm, 3 μm, 4 μm, or 5 μm, etc. In an embodiment of the present disclosure, the D50 particle size of the positive electrode electrolyte ranges from 1 μm to 4 μm. In another embodiment of the present disclosure, the D50 particle size of the positive electrode electrolyte ranges from 2 μm to 5 μm.

In an embodiment of the present disclosure, the mass ratio of the positive electrode active material to the positive electrode electrolyte is 1:(0.1-1). In some examples, the mass ratio of the positive electrode active material to the positive electrode electrolyte can be, but is not limited to, 1:0.1, 1:0.2, 1:0.4, 1:0.5, 1:0.7, 1:0.8, 1:0.9, or 1:1, etc. In an embodiment of the present disclosure, the mass ratio of the positive electrode active material to the positive electrode electrolyte can be 1:(0.1-0.5). In another embodiment of the present disclosure, the mass ratio of the positive electrode active material to the positive electrode electrolyte can be 1:(0.3-1).

In an embodiment of the present disclosure, the pore size of the pores ranges from 0.1 μm to 5 μm. When the pore size of the pores is smaller, the total length L₃ of the third type of contact interface can be reduced, and the adverse effect of the pores on the positive electrode plate can be reduced. In some examples, the pore size of the pores can be, but is not limited to, 0.1 μm, 1 μm, 2 μm, 3 μm, 4 μm, or 5 μm, etc. In an embodiment of the present disclosure, the pore size of the pores ranges from 0.1 μm to 3 μm. In another embodiment of the present disclosure, the pore size of the pores ranges from 2 μm to 5 μm. The volume and the pore size of the pores can be measured by means of SEM images.

In an embodiment of the present disclosure, the volume percentage of the pores in the positive electrode active material layer is less than or equal to 5%. When the pore volume in the positive electrode active material layer is smaller, the total length L₃ of the third type of contact interface can be reduced, thereby improving the electrochemical performance of the positive electrode plate. In some examples, the volume percentage of the pores in the positive electrode active material layer can be, but is not limited to, less than or equal to 5%, less than or equal to 4.5%, less than or equal to 3%, less than or equal to 3.5%, or less than or equal to 2%, etc. In an embodiment of the present disclosure, the volume percentage of the pores in the positive electrode active material layer can be less than or equal to 3.5%.

The present disclosure also includes a method for evaluating an electrochemical performance of a positive electrode plate, including:
providing the positive electrode plate, the positive electrode plate including the positive electrode current collector and the positive electrode active material layer on the surface of the positive electrode current collector, the positive electrode active material layer including the positive electrode active material and the positive electrode electrolyte, and pores existing within the positive electrode active material layer;
cutting the positive electrode plate along a thickness direction of the positive electrode plate to expose a vertical cross-section of the positive electrode active material layer;
taking at least one vertical cross-section of the positive electrode active material layer, and defining that, in the at least one vertical cross-section, the total length of the contact interface between the positive electrode active material and the positive electrode electrolyte is the total length L₁ of the first type of contact interface, the total length of the contact interface between the positive electrode active material and the positive electrode active material is the total length L₂ of the second type of contact interface, and the total length of the contact interface between the positive electrode active material and the pores is the total length L₃ of the third type of contact interface;
acquiring the total length L₁ of the first type of contact interface, the total length L₂ of the second type of contact interface and the total length L₃ of the third type of contact interface in the vertical cross-section of the positive electrode active material layer through a characterization means, and calculating the ratio L₁:L₂:L₃ of the total length L₁ of the first type of contact interface, the total length L₂ of the second type of contact interface and the total length L₃ of the third type of contact interface, and evaluating the electrochemical performance of the positive electrode plate based on whether L₁:L₂:L₃ satisfies L₁:L₂:L₃=(80-99):(1-20):(0-5), and a sum of L₁, L₂ and L₃ is 100.

The method for evaluating the electrochemical performance of the positive electrode plate is novel, has a simple evaluation process, has a wide application range, and can rapidly evaluate the electrochemical performance of the positive electrode plate.

In an embodiment of the present disclosure, the positive electrode plate is cut along the thickness direction of the positive electrode plate by an ion grinder to expose the vertical cross-section of the positive electrode active material layer; at least one vertical cross-section of the positive electrode active material layer is taken. In the at least one vertical cross-section, the total length of the contact interface between the positive electrode active material and the positive electrode electrolyte is denoted as the total length L₁ of the first type of contact interface, the total length of the contact interface between the positive electrode active material and the positive electrode active material is denoted as the total length L₂ of the second type of contact interface, and the total length of the contact interface between the positive electrode active material and pores is denoted as the total length L₃ of the third type of contact interface; the particle distribution characterization of the vertical cross-section of the positive electrode active material layer is acquired by an analysis software or manual calculation, the total length L₁ of the contact interface between the positive electrode active material and the positive electrode electrolyte, the total length L₂ of the contact interface between the positive electrode active material and the positive electrode active material, and the total length L₃ of the contact interface between the positive electrode active material and pores are acquired, and a sum of L₁, L₂ and L₃ is 100, the ratio L₁:L₂:L₃ of the three is calculated, and the electrochemical performance of the positive electrode plate is evaluated based on whether L₁:L₂:L₃ satisfies L₁:L₂:L₃=(80-99):(1-20):(0-5). When L₁:L₂:L₃ satisfies L₁:L₂:L₃=(80-99):(1-20):(0-5), the positive electrode plate has high ionic conductivity, high specific capacity and low resistance, and has improved overall electrochemical performance. When L₁:L₂:L₃ does not satisfy L₁:L₂:L₃=(80-99):(1-20):(0-5), the positive electrode plate has decreased ionic conductivity, low specific capacity and high resistance, and has decreased electrochemical performance compared to the example when L₁:L₂:L₃ satisfies the relation described above.

In the present disclosure, at least one vertical cross-section of the positive electrode active material layer is taken to perform the proportion statistics of the total length of the first type of contact interface, the total length of the second type of contact interface, and the total length of the third type of contact interface. The at least one vertical cross-section can be one or more (two or more) vertical cross-sections. Taking multiple vertical cross-sections for statistical analysis helps to more accurately evaluate the electrochemical performance of the positive electrode plate. The vertical cross-section can be a vertical cross-section along the length direction of the positive electrode active material layer, or a vertical cross-section along the width direction of the positive electrode active material layer, or a vertical cross-section passing through the central axis of the positive electrode active material layer. In some embodiments of the present disclosure, the vertical cross-section of the positive electrode active material layer can be obtained by cutting through the central axis of the positive electrode active material layer. When multiple cuts are performed and the cutting interval is small enough to obtain a sufficient number of vertical cross-sections, the statistical precision of various contact situations in the positive electrode plate can be further improved, and the acquired ratio L₁:L₂:L₃ is also closer to the real total area ratio of the three types of contacts in the positive electrode active material layer.

The present disclosure also includes a positive electrode plate. The positive electrode plate includes a positive electrode active material layer. The positive electrode active material layer includes a positive electrode active material and a positive electrode electrolyte, and pores exist within the positive electrode active material layer. In the positive electrode active material layer, the contact area between the positive electrode active material and the positive electrode electrolyte is denoted as the total area S₁ of the first type of contact interface, the contact area between different portions or particles of the positive electrode active material is denoted as the total area S₂ of the second type of contact interface, and the contact area between the positive electrode active material and the pores is denoted as the total area S₃ of the third type of contact interface. The area ratio of the total area S₁ of the first type of contact interface, the total area S₂ of the second type of contact interface, and the total area S₃ of the third type of contact interface satisfies S₁:S₂:S₃=(80-99):(1-20):(0-5), and a sum of S₁, S₂, and S₃ is 100.

The positive electrode plate described in the present disclosure has a high proportion of the total area S₁ of the first type of contact interface. In some aspects, the contact interface between the positive electrode active material and the positive electrode electrolyte in the active material layer is large, the ion transfer occurs widely, the pathways for ion intercalation and deintercalation are increased, and the ionic conductivity and specific capacity of the positive electrode plate are improved. The appropriate total area S₂ of the second type of contact interface, such as the contact interface between different portions or particles of positive electrode active materials, provides an appropriate number of electronic conduction pathways and maintains a low resistance of the positive electrode plate. The total area S₃ of the third type of contact interface reflects the contact area between the positive electrode active material and the pores; the contact may not participate in the construction of electronic conduction and ionic conduction pathways, may correspond to an ineffective contact, and may not affect the electrochemical performance of the positive electrode plate, and therefore the proportion of the total area S₃ of the third type of contact interface is low. In the positive electrode plate described in the present disclosure, by controlling the proportion range of three types of contacts in the positive electrode active material layer, such as the contact area between the positive electrode active material and the positive electrode electrolyte, the contact area between different portions or particles of the positive electrode active material, and the contact area between the positive electrode active material and pores, the number of ionic conduction pathways in the positive electrode plate can be increased, the appropriate number of electronic conduction pathways can be controlled, the ionic conductivity and specific capacity are improved, the resistance of the positive electrode plate is reduced, and thus the overall electrochemical performance of the positive electrode plate is improved.

The present disclosure further includes a solid-state battery. The solid-state battery includes the positive electrode plate provided in any one of the above embodiments and a solid-state electrolyte layer on a surface of the positive electrode plate. The solid-state battery described in the present disclosure has a high specific capacity, good safety performance, and improved electrochemical performance. Referring to FIG. 3, FIG. 3 is a schematic diagram of a cross-section structure of a solid-state battery according to an embodiment of the present disclosure. The solid-state battery includes a positive electrode plate 10, a negative electrode plate 30, and a solid-state electrolyte layer 20 between the positive electrode plate 10 and the negative electrode plate 30. The negative electrode plate 30 includes a negative electrode current collector 32 and a negative electrode active material layer 31 on a surface of the negative electrode current collector 32.

In one embodiment of the present disclosure, the solid-state electrolyte layer can improve the safety of the solid-state battery, and the solid-state electrolyte layer includes a solid-state electrolyte and a binder. The binder can improve the bonding ability of the components in the solid-state electrolyte layer and improve the bonding ability between the solid-state electrolyte layer and the negative electrode and positive electrode plates. In some examples, the binder can be, but is not limited to, at least one of polyvinylidene fluoride, polyvinylidene difluoride, polytetrafluoroethylene, polyethylene, polypropylene, polystyrene, polybutadiene, acrylic resin, epoxy resin, polyethylene oxide, sodium carboxymethyl cellulose, and styrene-butadiene latex. In one embodiment of the present disclosure, the binder may be polyvinylidene fluoride. In another embodiment of the present disclosure, the binder may be sodium carboxymethyl cellulose.

In one embodiment of the present disclosure, the solid-state electrolyte can include, but is not limited to, at least one of an organic polymer, an oxide, and a sulfide. The organic polymer can include, but is not limited to, at least one of polyethylene oxide, polypropylene oxide, polyvinylidene chloride, and polyvinylidene fluoride; the oxide can include, but is not limited to, at least one of lithium lanthanum titanium oxide, lithium lanthanum zirconium oxide, and fast ion conductors; and the sulfide can include, but is not limited to, at least one of a lithium-containing sulfide, an aluminum-containing sulfide, a phosphorus-containing sulfide, a silicon-containing sulfide, and a tin-containing sulfide. In one embodiment of the present disclosure, the solid-state electrolyte may be the lithium-containing sulfide, and the lithium-containing sulfide electrolyte can include, but is not limited to, at least one of Li₃PS₄, Li_{5.5}PS_{4.5}Cl_{1.5}, Li₇P₃S₁₁, Li₁₁GeP₂S₁₂, Li₆PS₅Cl, Li₇P₂S₈I, Li₁₀SnP₂S₁₂ and Li_{3.25}Ge_{0.25}P_{0.75}S₄. In another embodiment of the present disclosure, the solid-state electrolyte may be polypropylene oxide.

In one embodiment of the present disclosure, the particle size of the solid-state electrolyte particles ranges from 1 nm to 5 μm. In some examples, the particle size of the solid-state electrolyte particles can be, but is not limited to, 1 nm, 20 nm, 100 nm, 1.5 μm, 2 μm, 3 μm, or 5 μm, etc. In one embodiment of the present disclosure, the particle size of the solid-state electrolyte particles ranges from 1 nm to 500 nm. In another embodiment of the present disclosure, the particle size of the solid-state electrolyte particles ranges from 1 μm to 5 μm.

In one embodiment of the present disclosure, the negative electrode may be selected from related negative electrodes such as a graphite negative electrode, a silicon-based negative electrode, and lithium metal.

In one embodiment of the present disclosure, the negative electrode active material layer includes the negative electrode active material, and the negative electrode active material can include, but is not limited to, at least one of silicon, tin, germanium, lithium and alloys thereof, and carbon materials. The carbon material can include, but is not limited to, at least one of non-graphitized carbon, graphite, pyrolytic carbon, coke, activated carbon, or acetylene black. In one embodiment of the present disclosure, the negative electrode active material may be the carbon material. In another embodiment of the present disclosure, the negative electrode active material may be the silicon material.

In one embodiment of the present disclosure, when the negative electrode active material includes the silicon material, the negative electrode active material layer further includes a conductive agent. The conductive agent can increase the electrical conductivity between active materials and improve the electronic conductivity. In some examples, the conductive agent can include, but is not limited to, at least one of graphite, carbon black, acetylene black, and graphene. In one embodiment of the present disclosure, the conductive agent may be graphite. In another embodiment of the present disclosure, the conductive agent may be carbon black.

In one embodiment of the present disclosure, the negative electrode current collector can include, but is not limited to, at least one of copper, aluminum, nickel, and stainless steel. In one embodiment of the present disclosure, the negative electrode current collector may be a copper foil.

The present disclosure also includes an electric device, and the electric device includes the solid-state battery according to any one of the above embodiments. The electric device described in the present disclosure has improved overall performance and strong market competitiveness. The electric device includes mobile phones, tablets, watches, VR glasses, vehicles, etc. In an embodiment of the present disclosure, the solid-state battery can be used in a vehicle, thereby improving the safety of electricity usage of the vehicle. In another embodiment of the present disclosure, the solid-state battery can also be used in a mobile phone, thereby increasing the battery capacity of the mobile phone and improving the service life of the battery.

The effects of the technical solutions of the present disclosure are further described below through specific examples.

### Example 1

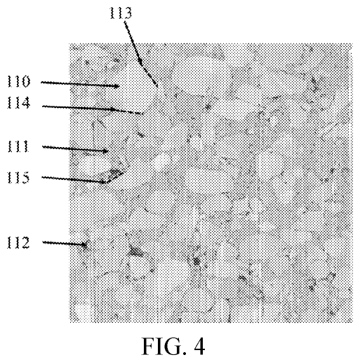

1. The positive electrode plate: the positive electrode active material (single crystal of (LiNi_{0.8}Co_{0.1}Mn_{0.1}O₂) with a D50 particle size of 4 μm) and the positive electrode electrolyte (Li_{5.5}PS_{4.5}Cl_{1.5} with a particle size of 1 μm) are mixed, the mass ratio of the positive electrode active material to the positive electrode electrolyte is 4:1, a mixed slurry is obtained, the mixed slurry is coated on the surface of the positive electrode current collector to obtain the positive electrode plate, and a vertical cross-section of the positive electrode active material layer along the thickness direction is randomly taken. FIG. 4 is a scanning electron microscope (SEM) image of the cross-section of the positive electrode active material layer according to Example 1 of the present disclosure. The positive electrode active material layer 11 includes the positive electrode active material 110 and the positive electrode electrolyte 111, and pores 112 exist within the positive electrode active material layer; the contact interface of the positive electrode active material 110 and the positive electrode electrolyte 111 is the first type of contact interface 113, the contact interface of the positive electrode active material 110 and the positive electrode active material 110 is the second type of contact interface 114, and the contact interface of the positive electrode active material 110 and the pores 112 is the third type of contact interface 115. The lengths of the three types of contact interfaces in the whole cross-section are statistically calculated, and the length ratio of the total length L₁ of the first type of contact interface, the total length L₂ of the second type of contact interface, and the total length L₃ of the third type of contact interface is 88:10:2.
2. The negative electrode plate: a lithium copper composite foil with a thickness of 20 μm is taken and cut into the negative electrode plate in the present disclosure.
3. The solid-state electrolyte layer: 980 g of lithium-containing sulfide electrolyte LPSCl is placed into 600 g of a xylene solution, wherein the xylene solution contains 20 g of butadiene rubber binder, and then heated and stirred to obtain a stable and uniform solution. The solution is continuously coated on a release film, and then dried at 333 K to obtain a self-supporting electrolyte film with a thickness of 40 μm, which is cut into the electrolyte layer plate.

### Example 2

The difference from the Example 1 is that the length ratio of the total length L₁ of the first type of contact interface, the total length L₂ of the second type of contact interface, and the total length L₃ of the third type of contact interface is 93:5:2.

### Example 3

The difference from the Example 1 is that the length ratio of the total length L₁ of the first type of contact interface, the total length L₂ of the second type of contact interface, and the total length L₃ of the third type of contact interface is 80:18:2.

### Example 4

The difference from the Example 1 is that the length ratio of the total length L₁ of the first type of contact interface, the total length L₂ of the second type of contact interface, and the total length L₃ of the third type of contact interface is 85:10:5.

### Example 5

The difference from the Example 1 is that the length ratio of the total length L₁ of the first type of contact interface, the total length L₂ of the second type of contact interface, and the total length L₃ of the third type of contact interface is 98:1:1.

### Comparative Example 1

The difference from the Example 1 is that the length ratio of the total length L₁ of the first type of contact interface, the total length L₂ of the second type of contact interface, and the total length L₃ of the third type of contact interface is 80:10:10.

### Comparative Example 2

The difference from the Example 1 is that the length ratio of the total length L₁ of the first type of contact interface, the total length L₂ of the second type of contact interface, and the total length L₃ of the third type of contact interface is 55:30:15.

### Performance Test

The positive electrode plate and the negative electrode plate prepared in the above examples and comparative examples and the solid-state electrolyte layer are used to form a solid-state battery, and battery performance is tested. The test method is as follows: 5 solid-state batteries prepared in each of the examples and comparative examples are taken, and the solid-state batteries are respectively subjected to charge-discharge cycle test at a 0.1C rate on a LAND CT 2001C secondary battery performance testing device, and the specific capacity of the positive electrode plate is calculated and recorded as Q1. Then, the solid-state batteries are subjected to charge-discharge test at a 0.5C rate, and the specific capacity is recorded as Q2, and the 0.5C/0.1C capacity retention rate is Q2/Q1*100%, recorded as the rate performance. The step is repeated, and when the battery capacity is lower than 80% of the initial discharge capacity during the cycle process, the cycle is terminated, and the cycle number is the cycle life of the solid-state battery. The results are shown in Table 1.

TABLE 1
Battery performance test results

| | Specific capacity | Rate performance | |
|---|---|---|---|
| | (mAh/g) | (%) | Cycle life (cycles) |
| Example 1 | 202 | 93.7 | 178 |
| Example 2 | 208 | 87.2 | 174 |
| Example 3 | 197 | 94.1 | 159 |
| Example 4 | 195 | 84.7 | 151 |
| Example 5 | 211 | 82.6 | 192 |
| Comparative | 192 | 88.5 | 147 |
| Example 1 | | | |
| Comparative | 172 | 77.1 | 82 |
| Example 2 | | | |

As can be seen from the data in Table 1, compared with Comparative Examples 1 and 2, the positive electrode plates prepared in Examples 1 to 5 have high specific capacity, improved rate performance, long cycle life, and better overall performance. This is because, in Examples 1 to 5, the length ratio of the total length L₁ of the first type of contact interface, the total length L₂ of the second type of contact interface, and the total length L₃ of the third type of contact interface satisfies L₁:L₂:L₃=(80-99):(1-20):(0-5), which can help ensure that the positive electrode plate has a large number of ionic conduction pathways and an appropriate number of electronic conduction pathways, improve the ionic conductivity and specific capacity, and reduce the resistance of the positive electrode plate. Comparative Examples 1 and 2 do not satisfy the above range, and thus batteries with improved overall performance may not be obtained.

In addition, as can be seen from the results of Examples 1 to 5, under the condition of satisfying L₁:L₂:L₃-(80-99):(1-20):(0-5), maintaining a high proportion of the total length L₁ of the first type of contact interface while appropriately increasing the proportion of the total length L₂ of the second type of contact interface and reducing the proportion of the total length L₃ of the third type of contact interface helps to better balance the ionic conductivity and the electronic conductivity, so that the positive electrode plate can better balance the high specific capacity, the rate performance, and the cycle performance.

The above are embodiments of the present disclosure, but should not be understood as a limitation of the scope of the present disclosure. It should be pointed out that several improvements and modifications can be made without departing from the principle of the present disclosure, and these improvements and modifications are within the scope of the present disclosure.

What is claimed is:

1. A positive electrode plate, comprising:
a positive electrode current collector; and
a positive electrode active material layer on a surface of the positive electrode current collector, the positive electrode active material layer including:
a positive electrode active material,
a positive electrode electrolyte, and
pores within the positive electrode active material layer, wherein
in a vertical cross-section of the positive electrode active material layer taken along a thickness direction,
a total length of a first type of contact interface between the positive electrode active material and the positive electrode electrolyte is a total length L₁,
a total length of a second type of contact interface between different portions or particles of the positive electrode active material is a total length L₂, and
a total length of a third type of contact interface between the positive electrode active material and the pores is a total length L₃; and
a length ratio of the total length L₁ of the first type of contact interface, the total length L₂ of the second type of contact interface, and the total length L₃ of the third type of contact interface satisfies L₁:L₂:L₃=(80-99):(1-20):(0-5), and a sum of L₁, L₂, and L₃ is 100.

2. The positive electrode plate according to claim 1, wherein
the length ratio of the total length L₁ of the first type of contact interface, the total length L₂ of the second type of contact interface; and
the total length L₃ of the third type of contact interface satisfies L₁:L₂:L₃=(85-95):(5-15):(0-2), and the sum of L₁, L₂, and L₃ is 100.

3. The positive electrode plate according to claim 1, wherein
a mass percentage of the positive electrode active material in the positive electrode active material layer ranges from 50% to 90%; and
a mass percentage of the positive electrode electrolyte in the positive electrode active material layer ranges from 10% to 50%.

4. The positive electrode plate according to claim 1, wherein
a volume percentage of the pores in the positive electrode active material layer is less than or equal to 5%; and
a pore size of the pores ranges from 0.1 μm to 5 μm.

5. The positive electrode plate according to claim 1, wherein
the positive electrode active material includes at least one of lithium iron phosphate, lithium cobalt oxide, lithium manganese oxide, lithium nickel cobalt aluminum oxide, lithium nickel cobalt manganese oxide, and lithium nickel manganese oxide; and
the positive electrode electrolyte includes at least one of an oxide electrolyte, a sulfide electrolyte, and a polymer electrolyte.

6. The positive electrode plate according to claim 5, wherein the sulfide electrolyte comprises at least one of Li₃PS₄, Li_{5.5}PS_{4.5}Cl_{1.5}, Li₇P₃S₁₁, Li₁₁GeP₂S₁₂, Li₆PS₅Cl, Li₇P₂S₈I, Li₁₀SnP₂S₁₂, and Li_{3.25}Ge_{0.25}P_{0.75}S₄.

7. A method for evaluating electrochemical performance of a positive electrode plate, comprising:
cutting a positive electrode plate along a thickness direction of the positive electrode plate to expose a vertical cross-section of a positive electrode active material layer of the positive electrode plate that is on a surface of a positive electrode current collector of the positive electrode plate, the positive electrode active material layer including:
a positive electrode active material, a positive electrode electrolyte, and
pores within the positive electrode active material layer
acquiring a total length L₁ of a first type of contact interface between the positive electrode active material and the positive electrode electrolyte, a total length L₂ of a second type of contact interface between different portions or particles of the positive electrode active material, and a total length L₃ of a third type of contact interface between the positive electrode active material and the pores;
calculating a ratio L₁:L₂:L₃ of the total length L₁ of the first type of contact interface, the total length L₂ of the second type of contact interface, and the total length L₃ of the third type of contact interface; and
evaluating the electrochemical performance of the positive electrode plate based on whether L₁:L₂:L₃ satisfies L₁:L₂:L₃=(80-99):(1-20):(0-5), and a sum of L₁, L₂, and L₃ is 100.

8. A positive electrode plate, the positive electrode plate comprising:
a positive electrode active material layer that includes:
a positive electrode active material,
a positive electrode electrolyte, and
pores within the positive electrode active material layer, wherein
in the positive electrode active material layer,
a total area of a first type of contact interface between the positive electrode active material and the positive electrode electrolyte is a total area S₁,
a total area of a second type of contact interface between different portions or particles the positive electrode active material is a total area S₂, and
a total area of a third type of contact interface between the positive electrode active material and the pores is a total area S₃; and
an area ratio of the total area S₁ of the first type of contact interface, the total area S₂ of the second type of contact interface, and the total area S₃ of the third type of contact interface satisfies S₁:S₂:S₃=(80-99):(1-20):(0-5), and a sum of S₁, S₂, and S₃ is 100.

9. The positive electrode plate according to claim 8, wherein
a mass percentage of the positive electrode active material in the positive electrode active material layer ranges from 50% to 90%; and
a mass percentage of the positive electrode electrolyte in the positive electrode active material layer ranges from 10% to 50%.

10. The positive electrode plate according to claim 8, wherein
a volume percentage of the pores in the positive electrode active material layer is less than or equal to 5%; and
a pore size of the pores ranges from 0.1 μm to 5 μm.

11. The positive electrode plate according to claim 8, wherein
the positive electrode active material includes at least one of lithium iron phosphate, lithium cobalt oxide, lithium manganese oxide, lithium nickel cobalt aluminum oxide, lithium nickel cobalt manganese oxide, and lithium nickel manganese oxide; and
the positive electrode electrolyte includes at least one of an oxide electrolyte, a sulfide electrolyte, and a polymer electrolyte.

12. The positive electrode plate according to claim 11, wherein the sulfide electrolyte comprises at least one of Li₃PS₄, Li_{5.5}PS_{4.5}Cl_{1.5}, Li₇P₃S₁₁, Li₁₁GeP₂S₁₂, Li₆PS₅Cl, Li₇P₂S₈I, Li₁₀SnP₂S₁₂, and Li_{3.25}Ge_{0.25}P_{0.75}S₄.

13. A solid-state battery, comprising:
a positive electrode plate; and
a solid-state electrolyte layer on a surface of the positive electrode plate, and the positive electrode plate including the positive electrode plate according to claim 1.

14. The solid-state battery according to claim 13, wherein
a mass percentage of the positive electrode active material in the positive electrode active material layer ranges from 50% to 90%; and
a mass percentage of the positive electrode electrolyte in the positive electrode active material layer ranges from 10% to 50%.

15. The solid-state battery according to claim 13, wherein
a volume percentage of the pores in the positive electrode active material layer is less than or equal to 5%; and
a pore size of the pores ranges from 0.1 μm to 5 μm.

16. The solid-state battery according to claim 13, wherein
the positive electrode active material includes at least one of lithium iron phosphate, lithium cobalt oxide, lithium manganese oxide, lithium nickel cobalt aluminum oxide, lithium nickel cobalt manganese oxide, and lithium nickel manganese oxide; and
the positive electrode electrolyte includes at least one of an oxide electrolyte, a sulfide electrolyte, and a polymer electrolyte.

17. A solid-state battery, comprising:
a positive electrode plate; and
a solid-state electrolyte layer on a surface of the positive electrode plate, and the positive electrode plate including the positive electrode plate according to claim 8.

18. The solid-state battery according to claim 17, wherein
a mass percentage of the positive electrode active material in the positive electrode active material layer ranges from 50% to 90%; and
a mass percentage of the positive electrode electrolyte in the positive electrode active material layer ranges from 10% to 50%.

19. The solid-state battery according to claim 17, wherein
a volume percentage of the pores in the positive electrode active material layer is less than or equal to 5%; and
a pore size of the pores ranges from 0.1 μm to 5 μm.

20. The solid-state battery according to claim 17, wherein
the positive electrode active material includes at least one of lithium iron phosphate, lithium cobalt oxide, lithium manganese oxide, lithium nickel cobalt aluminum oxide, lithium nickel cobalt manganese oxide, and lithium nickel manganese oxide; and
the positive electrode electrolyte includes at least one of an oxide electrolyte, a sulfide electrolyte, and a polymer electrolyte.
